(19) United States
(12) Patent Application Publication
(10) Pub. No.: US 2025/0318063 A1
(43) Pub. Date: Oct. 9, 2025

(54) SUBSTRATE LOADING UNIT AND METHOD OF MANUFACTURING DISPLAY DEVICE BY USING THE SAME

(71) Applicant: Samsung Display Co., LTD., Yongin-si (KR)

(72) Inventors: SAEROM KIM, Yongin-si (KR); JIYOUNG WANG, Yongin-si (KR)

(21) Appl. No.: 19/022,353

(22) Filed: Jan. 15, 2025

(30) Foreign Application Priority Data
Apr. 4, 2024 (KR) 10-2024-0046234

(51) Int. Cl. H05K 5/03; C03C 15/00; C03C 21/00

(52) U.S. Cl. CPC H05K 5/03; C03C 15/00; C03C 21/002

(57) ABSTRACT

A method of manufacturing a display device includes providing a preliminary glass, loading the preliminary glass on a first substrate loading unit, performing a (1-1)-th etching process of etching a surface of the preliminary glass by immersing the first substrate loading unit in an etching liquid, rotating the first substrate loading unit about a rotation axis being parallel to a first direction and turning the first substrate loading unit over, performing a (1-2)-th etching process of re-etching the surface of the preliminary glass by immersing the first substrate loading unit in the etching liquid, and strengthening the preliminary glass.

This application claims priority to Korean Patent Application No. 10-2024-0046234, filed on Apr. 4, 2024, and all the benefits accruing therefrom under 35 U.S.C. § 119, the content of which in its entirety is herein incorporated by reference.

### BACKGROUND

### 1. Field

Embodiments of the disclosure described herein relate to a substrate loading unit, and a method of manufacturing a display device by the same.

### 2. Description of the Related Art

A display device provides images to the user, and is used in various multimedia devices, such as televisions, mobile phones, tablet computers, and game consoles. A display device includes various modules to display images. Furthermore, the display device includes a window for protecting the modules of the display device.

The window may be prevented from being easily damaged by an external impact through an etching process and a strengthening process. The etching process and the strengthening process may be performed after the window is loaded on the substrate loading unit.

### SUMMARY

Embodiments of the disclosure provide a substrate loading unit that is rotated to uniformly etch a surface of a window when the window is etched after being loaded on the substrate loading unit, and a method of manufacturing a display device by the same.

In an embodiment, a method of manufacturing a display device includes providing a preliminary glass, loading the preliminary glass on a first substrate loading unit, performing a (1-1)-th etching process of etching a surface of the preliminary glass by immersing the first substrate loading unit in an etching liquid, rotating the first substrate loading unit about a rotation axis being parallel to a first direction and turning the first substrate loading unit over, performing a (1-2)-th etching process of re-etching the surface of the preliminary glass by immersing the first substrate loading unit in the etching liquid, and strengthening the preliminary glass.

In an embodiment, a substrate loading unit includes a plurality of main frames each having a plane defined by a first direction and a second direction crossing the first direction, and being spaced apart from each other in the first direction, a plurality of first support parts disposed between inner surfaces of the plurality of main frames facing each other in the first direction, and disposed on a lower side of a preliminary glass disposed between the plurality of main frames and opposite sides of the preliminary glass, which are opposite to each other in the second direction, and a rotation driving part disposed on an outer side of any one of the plurality of main frames.

### BRIEF DESCRIPTION OF THE DRAWINGS

The above and other embodiments, advantages and features of the disclosure will become apparent by describing in detail embodiments thereof with reference to the accompanying drawings.

FIG. 1 is a perspective view of an embodiment of a substrate loading unit according to the disclosure.

FIG. 2 is a perspective view illustrating an attachment and detachment of second support parts illustrated in FIG. 1.

FIG. 3 is a perspective view illustrating an electronic device that is manufactured by the substrate loading unit of FIG. 1.

FIG. 4 is a view illustrating a folding state of the electronic device illustrated in FIG. 3.

FIG. 5 is an exploded perspective view of the electronic device illustrated in FIG. 3.

FIG. 6 is a cross-sectional view of a display device illustrated in FIG. 5.

FIGS. 7A and 7B are flowcharts illustrating a method of manufacturing the window illustrated in FIG. 5.

FIG. 8 is a perspective view illustrating a cutting process.

FIGS. 9A and 9B are perspective views illustrating an operation of loading a preliminary glass on the substrate loading unit illustrated in FIG. 1.

FIGS. 10A to 10F are views illustrating a first etching and cleaning operations.

FIG. 11A is a graph depicting an etching amount according to a comparative example.

FIG. 11B is a graph depicting an embodiment of an etching amount according to the disclosure.

FIG. 12 is a view illustrating a strengthening process of FIG. 7A.

FIGS. 13A and 13B are views illustrating a process of assembling a display module and a window.

### DETAILED DESCRIPTION

In the specification, when it is mentioned that a component (or an area, a layer, a part, or the like) is “disposed on”, “connected to”, or “coupled to” another component, it means that the former component may be directly disposed on, connected to, or coupled to the latter component or a third component may be disposed between the components.

The same reference numerals denote the same components. Furthermore, in the drawings, thicknesses, ratios, dimensions of the components are exaggerated for an effective description of the technical contents. The term “and/or” includes one or more combinations that may be defined by the associated components.

Furthermore, in describing the various components, the terms, such as first and second may be used, but the disclosure is not limited by the terms. The terms are simply for distinguishing the components. For example, a first component may be named a second component, and similarly the second component also may be named the first component while not departing from the scope of the disclosure. A singular expression includes a plural expression unless an exemption is explicitly described in the context.

Furthermore, the terms, such as “under”, “below”, “on”, and “above”, are used to describe an associative relationship between the components illustrated in the drawings. The terms are relative concepts, and are described with respect to directions indicated in the drawings.

In the specification, the expression of “directly disposed” may mean that none of a layer, a film, an area, and a plate is added between a part, such as the layer, the film, the area, and the plate, and another part. For example, the expression of “directly disposed” may mean that the two layers or two members are disposed while an additional member, such as an adhesive member, is not used therebetween.

Unless otherwise defined, all terms, including technical and scientific terms, used herein have the same meaning as commonly understood by those skilled in the art to which the disclosure pertains. It will be further understood that terms, such as those defined in commonly used dictionaries, should be interpreted as having a meaning that is consistent with their meaning in the context of the specification and relevant art and should not be interpreted in an idealized or overly formal sense unless expressly so defined herein.

Hereinafter, embodiments of the disclosure will be described with reference to the drawings.

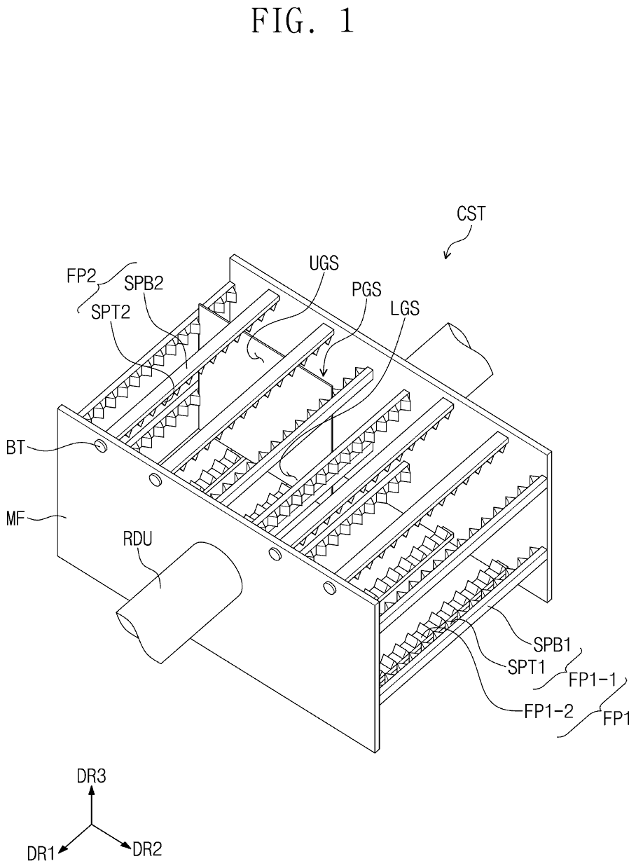

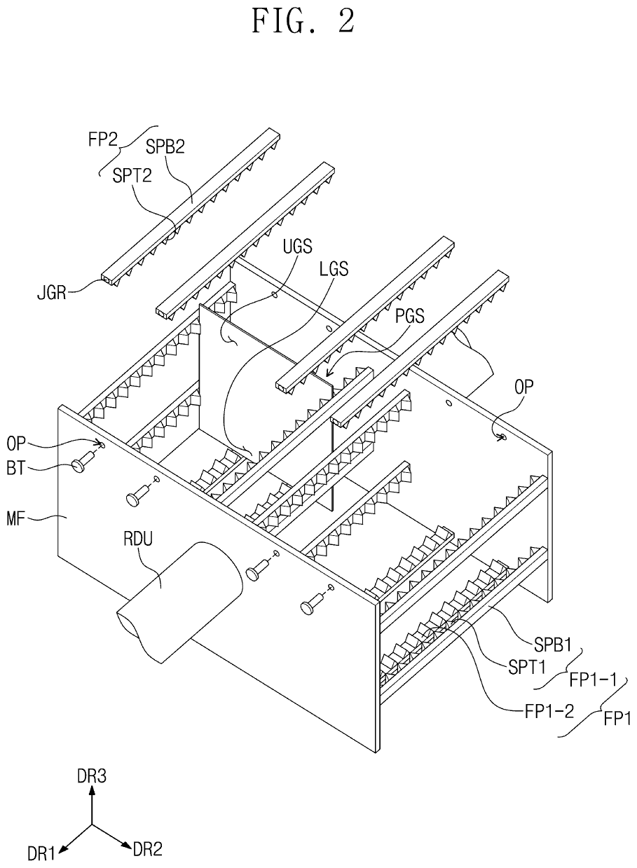

FIG. 1 is a perspective view of an embodiment of a substrate loading unit according to the disclosure. FIG. 2 is a perspective view illustrating an attachment and detachment of second support parts illustrated in FIG. 1.

Referring to FIGS. 1 and 2, a substrate loading unit CST may include a plurality of main frames MF, a plurality of rotation driving parts RDU, a plurality of first support parts FP1, a plurality of second support parts FP2, and a plurality of fixing screws BT.

The main frames MF may be disposed in a first direction DR1. The main frames MF may be parallel to a plane that is defined by a second direction DR2 and a third direction DR3 that cross the first direction DR1.

Hereinafter, a direction that substantially perpendicularly crosses the plane defined by the first and second directions DR1 and DR2 is defined as the third direction DR3. Furthermore, in the specification, “when viewed in a plan view” may be defined as viewed in the third direction DR3.

The main frames MF may have a quadrangular shape, e.g., rectangular shape having long sides that extend in the second direction DR2 and short sides that extend in the third direction DR3. However, this is merely one of embodiments, and the shape of the main frames MF is not limited thereto.

A plurality of openings OP may be defined in main frames MF. The openings OP may be defined in the second direction DR2 to be adjacent to an upper side of the main frames MF.

First support parts FP1 and second support parts FP2 may be disposed between inner surfaces of the main frames MF that face each other in the first direction DR1.

The first support parts FP1 may extend in the first direction DR1. The first support parts FP1 may include (1-1)-th support parts FP1-1 and (1-2)-th support parts FP1-2. The (1-1)-th support parts FP1-1 may be disposed on an upper side of the (1-2)-th support parts FP1-2.

The (1-1)-th support parts FP1-1 may be arranged in the second direction DR2 and the third direction DR3. In an embodiment, four (1-1)-th support parts FP1-1 may be arranged in the second direction DR2, and two (1-1)-th support parts FP1-1 may be arranged in the third direction DR3. Among the first bar portions SPB1 arranged in the second direction DR2, two pairs of first bar portions SPB1 may be arranged in the second direction DR2.

Each of the (1-1)-th support parts FP1-1 may include a first bar portion SPB1 and a first fixed portion SPT1. The first bar portions SPB1 may extend in the first direction DR1. Opposite sides of the first bar portions SPB1, which are opposite to each other in the first direction DR1 may be coupled to the main frames MF.

The first fixed portions SPT1 may be coupled to the first bar portions SPB1. The first fixed portions SPT1 may be disposed on inner surfaces of a pair of first bar portions SPB1, which face each other. The first fixed portions SPT1 may be arranged on inner surfaces of the first bar portions SPB1 in the first direction DR1.

The first fixed portions SPT1 disposed on the inner surfaces of the pair of first bar portions SPB1 may face each other in the second direction DR2. The first fixed portions SPT1 that face each other in the second direction DR2 may be arranged to correspond to each other.

In an embodiment, the first fixed portions SPT1 have a triangular column shape, but the shape of the first fixed portions SPT1 is not limited thereto, and may have a cylindrical or polygonal column shape.

The (1-2)-th support parts FP1-2 may be disposed between inner surfaces of the main frames MF. The (1-2)-th support parts FP1-2 may be disposed on a lower side of the (1-1)-th support parts FP1-1. The (1-2)-th support parts FP1-2 may be arranged in the second direction DR2.

The first fixed portions SPT1 of the (1-2)-th support parts FP1-2 have substantially the same structure as that of the (1-1)-th support parts FP1-1, except for being disposed on the upper surface of the first bar portions SPB1, and thus, a description of the (1-2)-th support parts FP1-2 will be omitted.

A preliminary glass PGS may be loaded on the substrate loading unit CST. The preliminary glass PGS may be disposed between a pair of (1-1)-th support parts FP1-1. The preliminary glass PGS may be disposed between inner surfaces of the first bar portions SPB1, which face each other in the second direction DR2. The preliminary glass PGS may be disposed between first fixed portions SPT1 that are adjacent to each other in the first direction DR1. In the description, an expression that two components are adjacent to each other may mean that the two components are immediately next to each other, but is not limited thereto.

The preliminary glass PGS may be disposed on the (1-2)-th support parts FP1-2. Hereinafter, a portion of the preliminary glass PGS, which is adjacent to the (1-2)-th support parts FP1-2, may be defined as a lower area LGS. That is, the lower area LGS may be closer to the (1-2)-th support parts FP1-2 than to the second support parts FP2. The lower area LGS may be disposed between the first fixed portions SPT1 of the (1-2)-th support parts FP1-2, which are adjacent to each other in the first direction DR1.

The second support parts FP2 may be disposed on the preliminary glass PGS. After the preliminary glass PGS is fixed by the first support parts FP1, the second support parts FP2 may be disposed on the preliminary glass PGS. The second support parts FP2 may face the (1-2)-th support parts FP1-2 in the third direction DR3. Hereinafter, a portion of the preliminary glass PGS, which is adjacent to the second support parts FP2, may be defined as an upper area UGS. That is, the upper area UGS may be closer to the second support parts FP2 than to first support parts FP1.

The second support parts FP2 may include second bar portions SPB2 and second fixed portions SPT2. The second bar portions SPB2 may extend in the first direction DR1. The second bar portions SPB2 may be disposed in the second direction DR2.

The second bar portions SPB2 may be coupled to the main frames MF. Coupling recesses JGR may be defined on opposite sides of the second bar portions SPB2, which are opposite to each other in the first direction DR1. The fixing screws BT may be inserted into openings OP that are defined in the main frames MF, and may be coupled to coupling recesses JGR. Accordingly, the second bar portions SPB2 may be fixed between the main frames MF.

The second fixed portions SPT2 may be disposed on one side of the second bar portions SPB2, which faces the preliminary glass PGS. The second fixed portions SPT2 may be disposed in the first direction DR1 on side surfaces of the second bar portions SPB2. The upper area UGS of the preliminary glass PGS may be disposed between the second fixed portions SPT2 that are adjacent to each other in the first direction DR1. Accordingly, the second support parts FP2 may fix an upper side of the preliminary glass PGS.

Rotation driving parts RDU may be disposed on the outer surfaces of the main frames MF. In an embodiment, the rotation driving parts RDU may be disposed at the centers of the outer surfaces of the main frames MF.

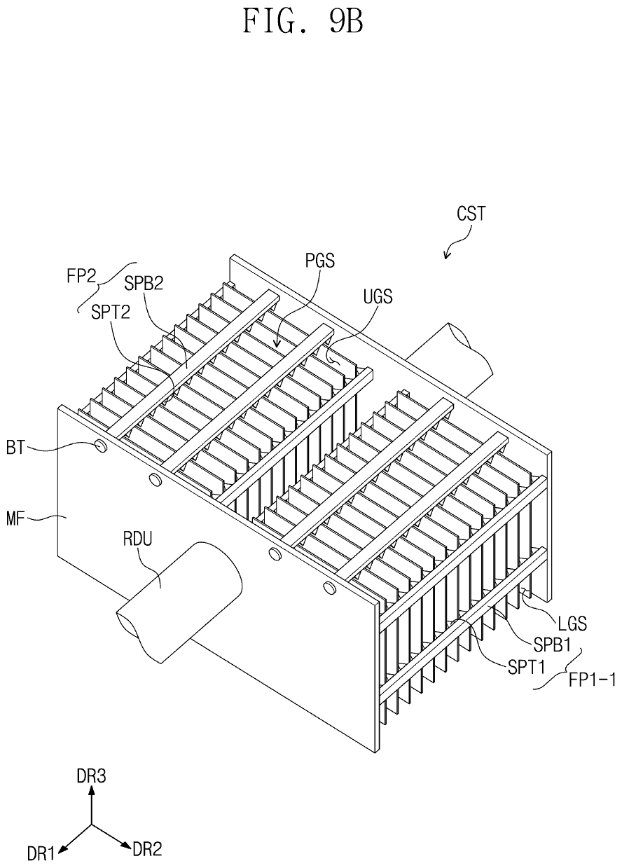

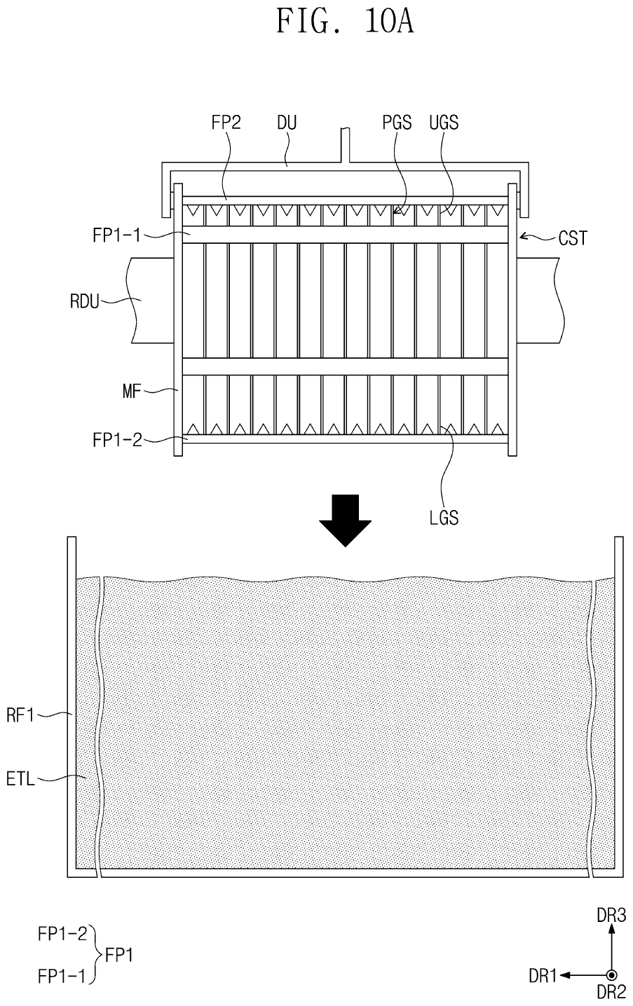

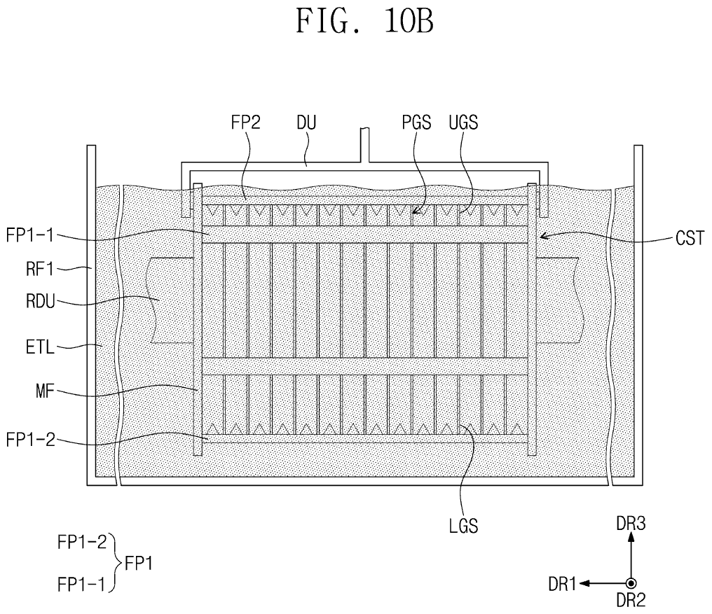

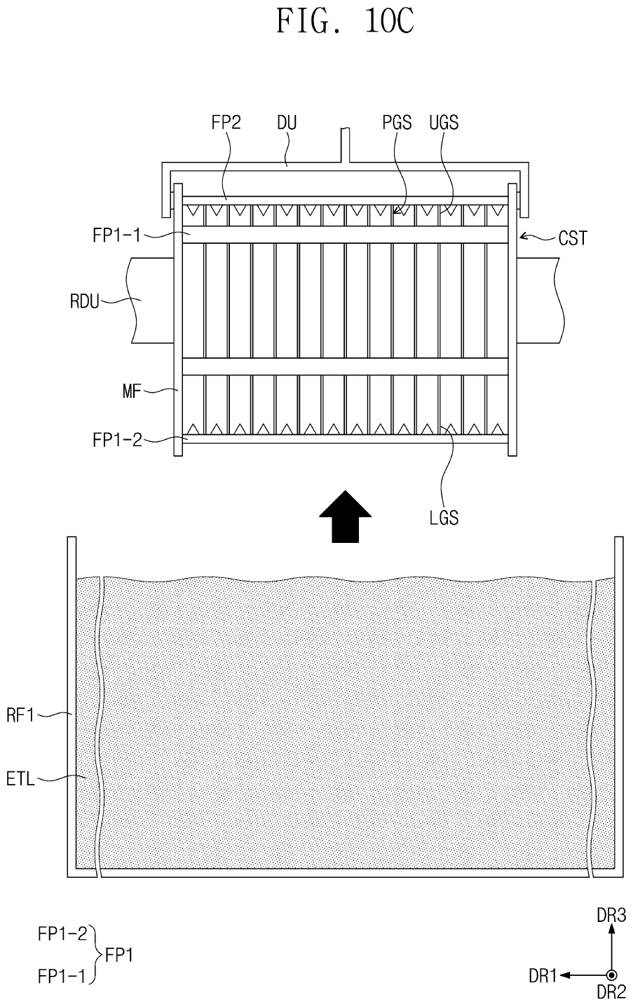

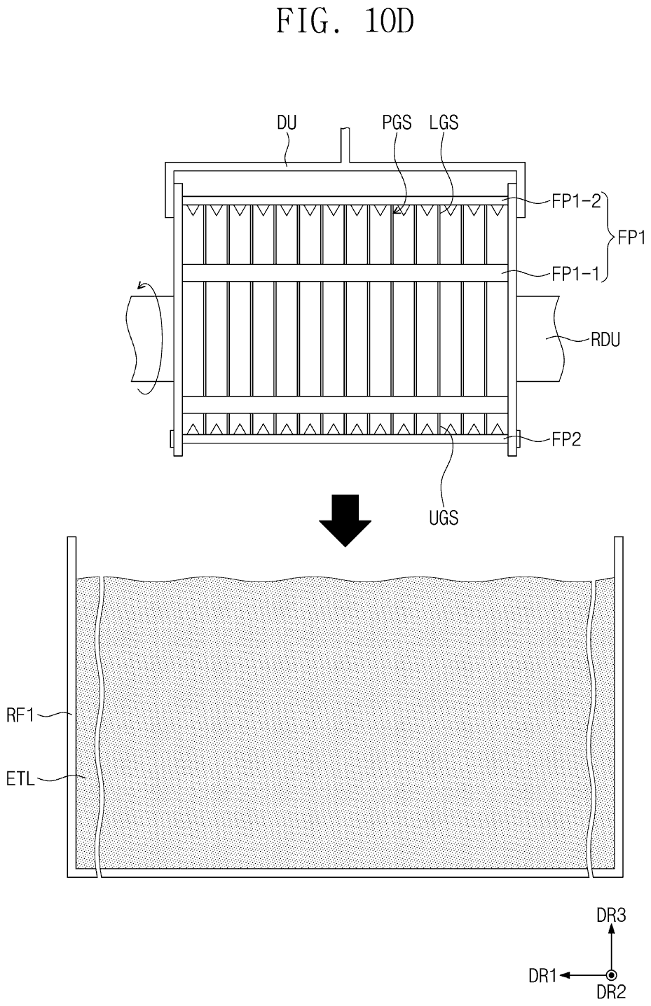

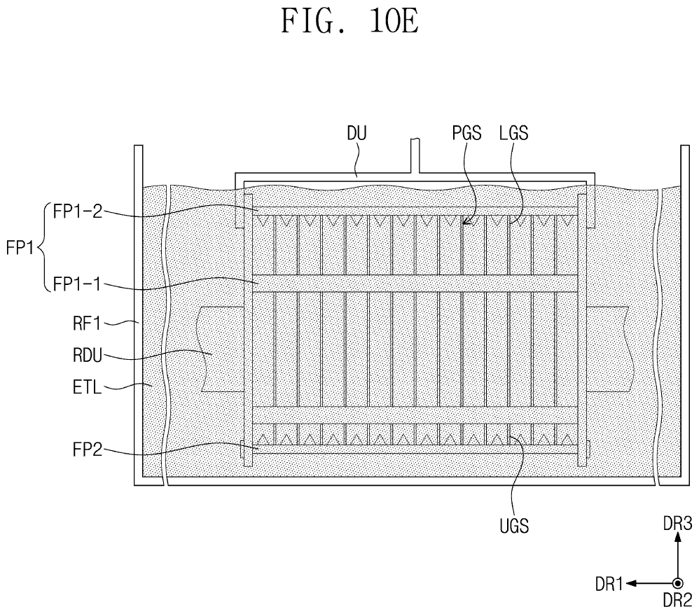

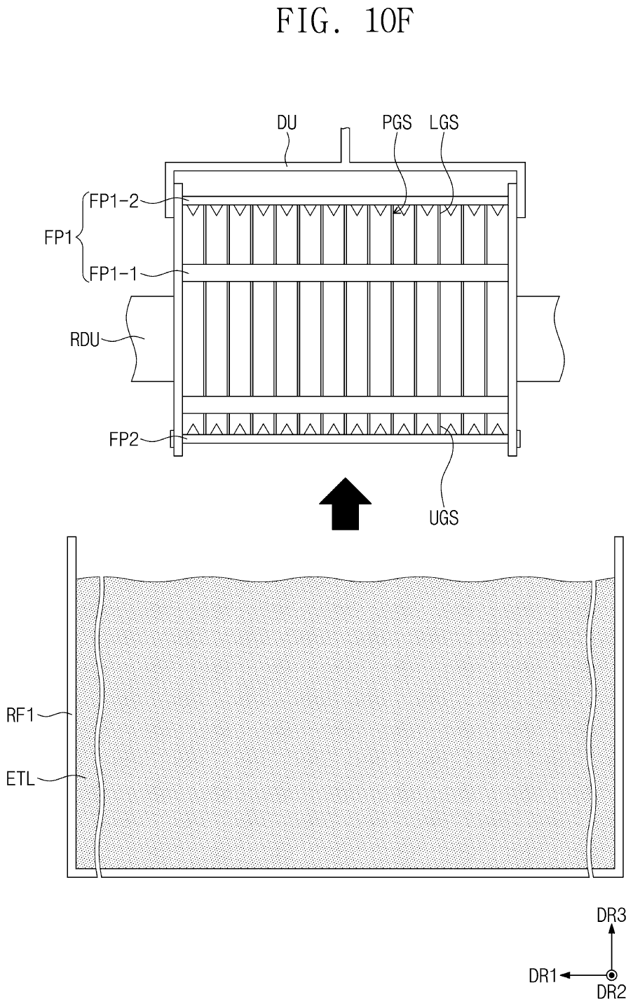

The rotation driving parts RDU may be rotated around a rotation axis that is parallel to the first direction DR1. When the rotation driving parts RDU are rotated, the main frames MF connected to the rotation driving parts RDU, the first support parts FP1 and the second support parts FP2 connected to the main frames MF, and the preliminary glass PGS disposed between the first support parts FP1 and second support parts FP2 may be rotated about the rotation axis that is parallel to the first direction DR1. As the preliminary glass PGS is rotated, the upper area UGS may be disposed on a lower side of a lower area LGS. The rotation of preliminary glass PGS will be described in detail in FIG. 10D.

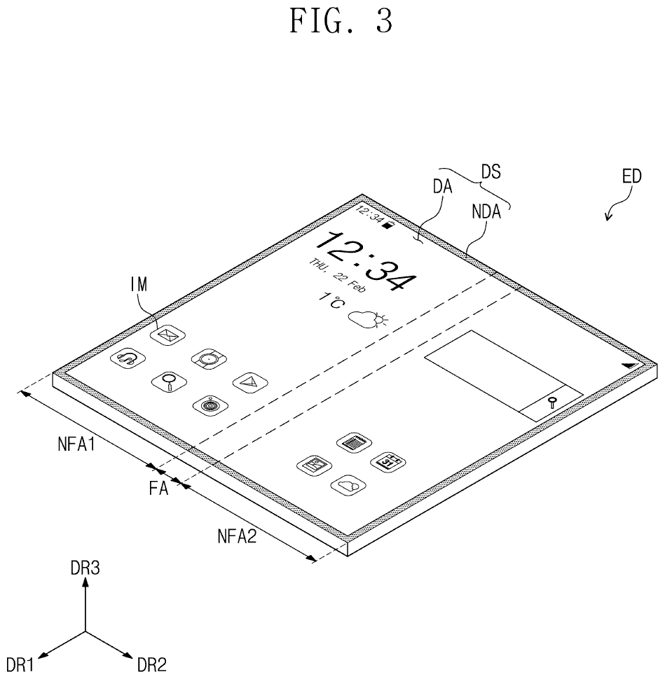

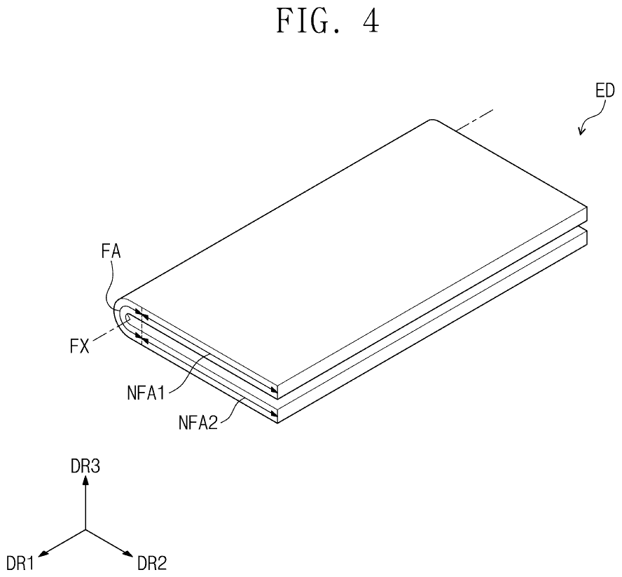

FIG. 3 is a perspective view illustrating an electronic device that is manufactured by the substrate loading unit of FIG. 1. FIG. 4 is a view illustrating a folding state of the electronic device illustrated in FIG. 3.

Referring to FIG. 3, an electronic device ED in an embodiment of the disclosure may have a quadrangular shape, e.g., rectangular shape having short sides that extend in the first direction DR1 and long sides that extend in the second direction DR2. However, the disclosure is not limited thereto, and the electronic device ED may have various shapes, such as a circular shape and a polygonal shape. The electronic device ED may be flexible.

The electronic device ED may include a folding area FA and a plurality of non-folding areas NFA1 and NFA2. The non-folding areas NFA1 and NFA2 may include a first non-folding area NFA1 and a second non-folding area NFA2. The folding area FA may be disposed between the first non-folding area NFA1 and the second non-folding area NFA2. The folding area FA, the first non-folding area NFA1, and the second non-folding area NFA2 may be arranged in the second direction DR2.

In an embodiment, one folding area FA and two non-folding areas NFA1 and NFA2 are illustrated, but the numbers of the folding areas FA and the non-folding areas NFA1 and NFA2 are not limited thereto. In an embodiment, the electronic device ED may include a plurality of, that is, two or more two non-folding areas and a plurality of folding areas that are disposed between the non-folding areas, for example.

An upper surface of the electronic device ED may be defined as a display surface DS, and the display surface DS may have a plane that is defined by the first direction DR1 and the second direction DR2. Images IM that are generated by the electronic device ED may be provided to the user through the display surface DS.

The display surface DS may include a display area DA and a non-display area NDA around the display area DA. The display area DA may display an image, and the non-display area NDA may not display an image. The non-display area NDA may define a periphery of the electronic device ED, which surrounds the display area DA and is printed in a predetermined color.

Referring to FIG. 4, the electronic device ED may be a foldable electronic device ED that is folded or unfolded. In an embodiment, the folding area FA may be curved with respect a folding axis FX that is parallel to the first direction DR1 so that the electronic device ED may be folded, for example. The folding axis FX may be defined as a long axis that is parallel to the long sides of the electronic device ED. When the electronic device ED is folded, the first non-folding area NFA1 and the second non-folding area NFA2 may face each other, and the electronic device ED may be in-folded to prevent the display surface DS from being exposed to an outside. However, the embodiments of the disclosure are not limited thereto. In an embodiment, the electronic device ED may be out-folded so that the display surface DS is exposed to the outside with respect to the folding axis FX, for example. Furthermore, although not illustrated, the electronic device ED may be in-folded and out-folded at the same time.

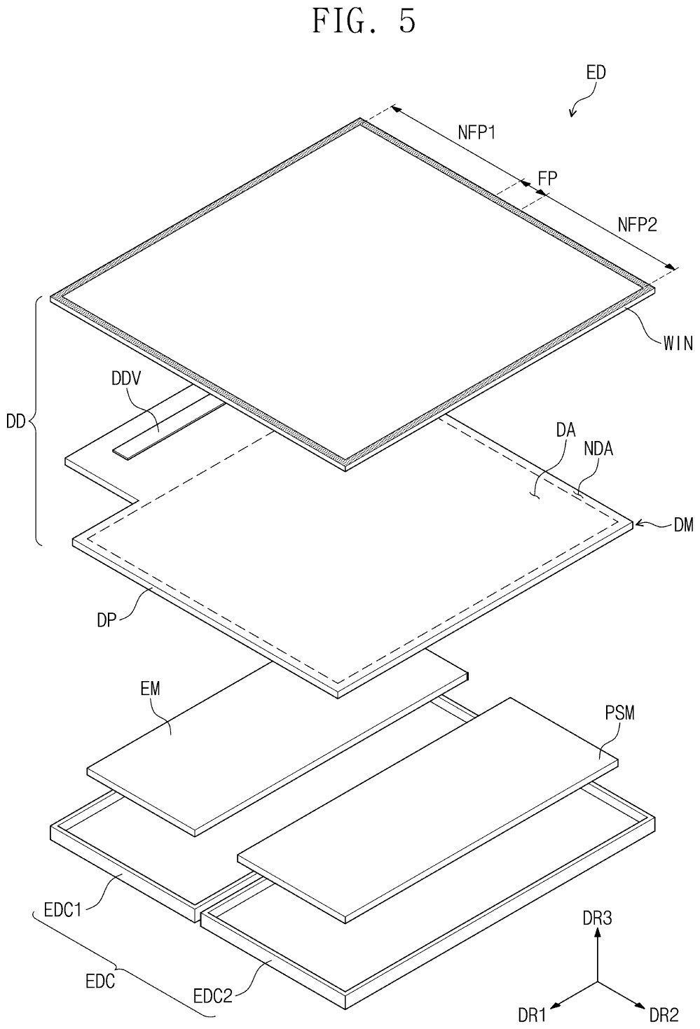

FIG. 5 is an exploded perspective view of the electronic device illustrated in FIG. 3.

Referring to FIG. 5, the electronic device ED may include a display device DD, an electronic module EM, a power supply module PSM, and a case EDC. Although not illustrated, the electronic device ED may further include a mechanical structure (e.g., a hinge) for controlling the folding operation of the display device DD.

The display device DD may create images and sense an external input. The display device DD may include a window WIN and a display module DM. A window WIN may provide a front surface of the electronic device ED. The window WIN may be disposed on the display module DM to protect the display module DM. The window WIN may transmit light that is generated in the display module DM, and provide it to the user.

The window WIN may include a first non-folding part NFP1, a folding part FP, and a second non-folding part NFP2 that are arranged in the first direction DR1. The folding part FP may be disposed between the first non-folding part NFP1 and the second non-folding part NFP2. The first non-folding part NFP1 may overlap the first non-folding area NFA1 of FIG. 3. The folding part FP may overlap the folding area FA of FIG. 3. The second non-folding part NFP2 may overlap the second non-folding area NFA2 of FIG. 3.

The display module DM may include a display panel DP. In FIG. 5 that only the display panel DP is illustrated in the stacked structure of the display module DM, but substantially, the display module DM may further include a plurality of components that are disposed on an upper side and a lower side of the display panel DP. The display panel DP may include a display area DA and a non-display area NDA corresponding to the display area DA and non-display area NDA of the electronic device ED of FIG. 3.

The display module DM may include a data driving part DDV that is disposed on the non-display area NDA of the display panel DP. The data driving part DDV may be manufactured in the form of an integrated circuit chip, and may be disposed (e.g., mounted) on the non-display area NDA. However, the disclosure is not limited thereto, and the data driving part DDV may be disposed (e.g., mounted) on a flexible circuit board that is connected to the display panel DP.

The electronic module EM and the power supply module PSM may be disposed on a lower side of the display device DD. Although not illustrated, the electronic module EM and the power supply module PSM may be connected to each other through a separate flexible circuit board. The electronic module EM may control an operation of the display device DD. The power supply module PSM may supply electric power to the electronic module EM.

The case EDC may accommodate the display device DD, the electronic module EM, and the power supply module PSM. The case EDC may include two first and second cases EDC1 and EDC2 to fold the display device DD. The first and second cases EDC1 and EDC2 may extend in the second direction DR2 and may be arranged in the first direction DR1.

Although not illustrated, the electronic device ED may further include a hinge structure for connecting the first and second cases EDC1 and EDC2. The case EDC may be coupled to the window WIN. The case EDC may protect the display device DD, the electronic module EM, and the power supply module PSM.

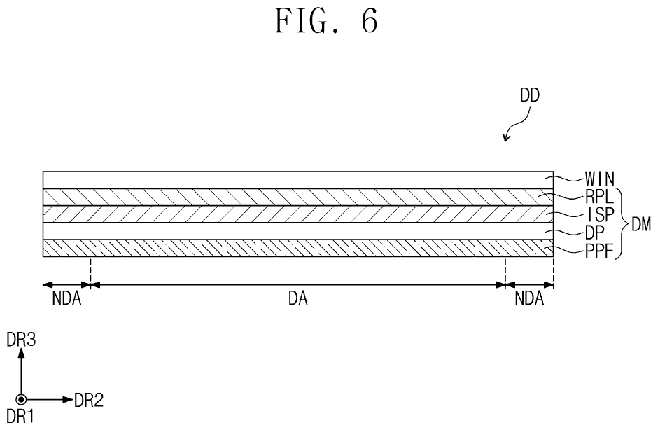

FIG. 6 is a cross-sectional view of a display device illustrated in FIG. 5.

Referring to FIG. 6, the display device DD may include a window WIN and a display module DM. The display module DM may include a display panel DP, an input sensing part ISP, a reflection preventing layer RPL, and a panel protecting film PPF.

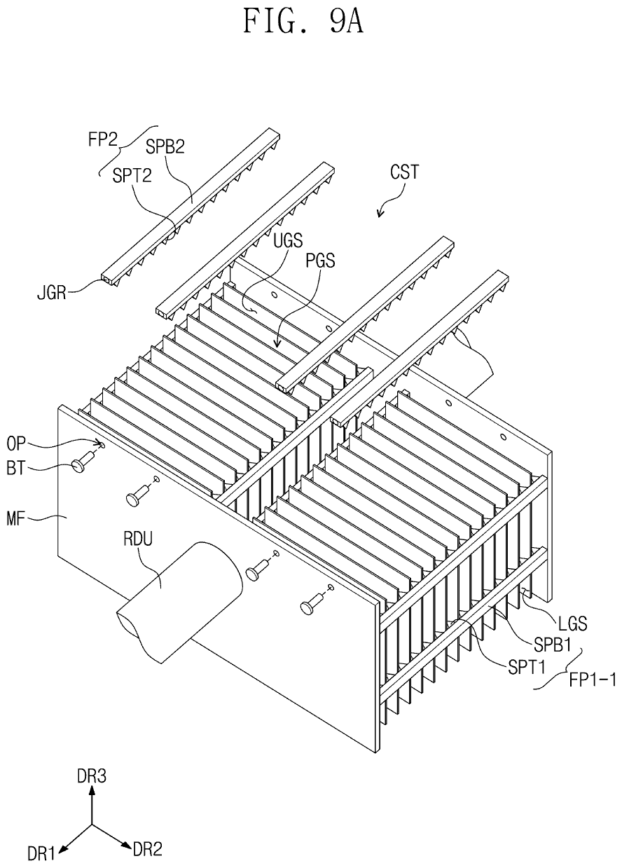

The window WIN may be manufactured by the substrate loading unit CST illustrated in FIG. 1. A plurality of preliminary glasses PGS, (refer to FIG. 1) may be loaded on the substrate loading unit CST illustrated in FIG. 1. When the display device DD is manufactured, the preliminary glasses PGS (refer to FIG. 1) may be loaded on the substrate loading unit CST and may be etched. The etching of preliminary glasses PGS (refer to FIG. 1) will be described in detail in FIGS. 9A to 10F.

The display panel DP may be a flexible display panel. The display panel DP in an embodiment of the disclosure may be a light-emitting display panel, and is not particularly limited. In an embodiment, the display panel DP may be an organic light-emitting display panel or an inorganic light-emitting display panel, for example. A light-emitting layer of the organic light-emitting display panel may include an organic light-emitting material. A light-emitting layer of the inorganic light-emitting display panel may include quantum dots and quantum rods.

An input sensing part ISP may be disposed on the display panel DP. The input sensing part ISP may include a plurality of sensing parts (not illustrated) for sensing an external input in a capacitive scheme. The input sensing part ISP may be manufactured directly on the display panel DP when the display device DD is manufactured. However, the disclosure is not limited thereto, and the input sensing part ISP may be manufactured as a panel that is separate from the display panel DP and may be attached to the display panel DP through an adhesion layer.

A reflection preventing layer RPL may be disposed on the input sensing part ISP. The reflection preventing layer RPL may be manufactured directly on the input sensing part ISP when the display device DD is manufactured. However, the disclosure is not limited thereto, and the reflection preventing layer RPL may be manufactured as a separate panel and may be attached to the input sensing part ISP by an adhesion layer.

The reflection preventing layer RPL may be defined as an external light reflection preventing film. The reflection preventing layer RPL may decrease a reflectance of external light that is input from an upper side of the display device DD toward the display panel DP. The external light may not be visible to the user due to the reflection preventing layer RPL.

When the external light that has traveled toward the display panel DP is reflected by the display panel DP and is provided to the external user again, the user may perceive the external light like a mirror. To prevent this phenomenon, In an embodiment, the reflection preventing layer RPL may include a plurality of color filters that display the same color as that of the pixels of the display panel DP.

The color filters may filter the external light with the same color as that of the pixels. In this case, the external light may not be visible to the user. However, the disclosure is not limited thereto, and the reflection preventing layer RPL may include a phase retarder and/or a polarizer to decrease the reflectance of the external light.

The window WIN may be disposed on the reflection preventing layer RPL. The window WIN may protect the display panel DP, the input sensing part ISP, and the reflection preventing layer RPL from external scratches and impacts.

A panel protecting film PPF may be disposed on a lower side of the display panel DP. The panel protecting film PPF may protect a lower side of the display panel DP. The panel protecting film PPF may include a flexible plastic material, such as polyethyleneterephthalate (“PET”).

Although not illustrated, the adhesion layer may be disposed between the display panel DP and the panel protecting film PPF, and the display panel DP and the panel protecting film PPF may be combined with each other by the adhesion layer. Although not illustrated, the adhesion layer may be disposed between the window WIN and the reflection preventing layer RPL, and the window WIN and the reflection preventing layer RPL may be combined each other by the adhesion layer.

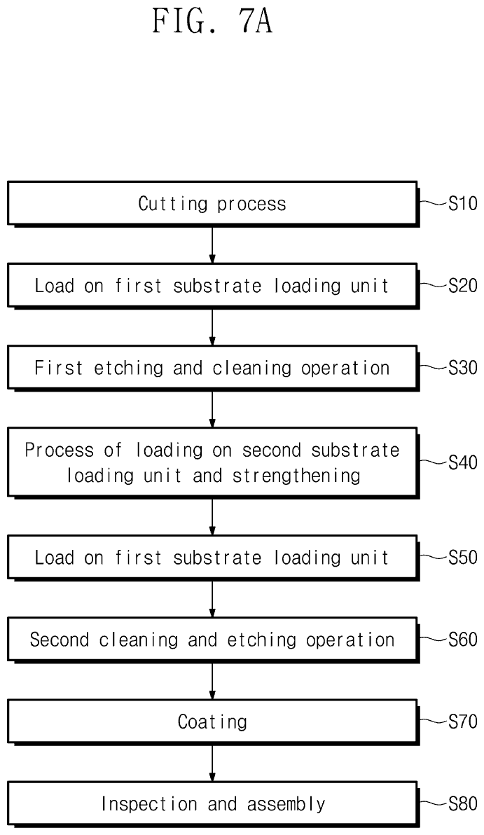

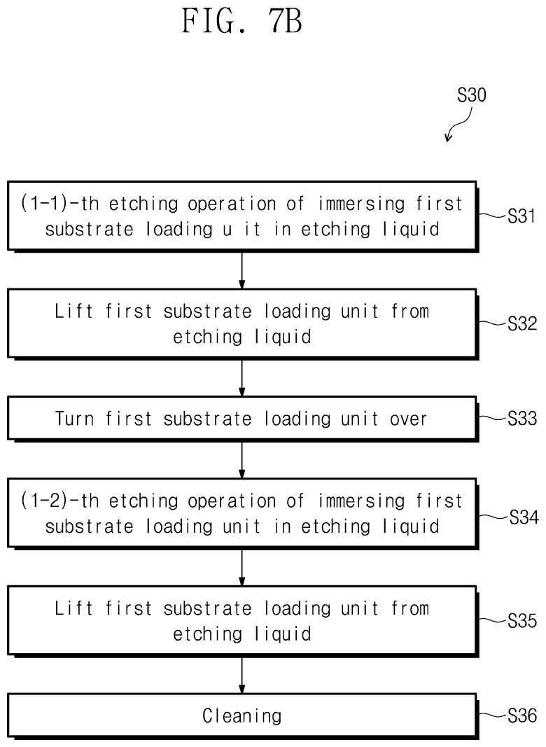

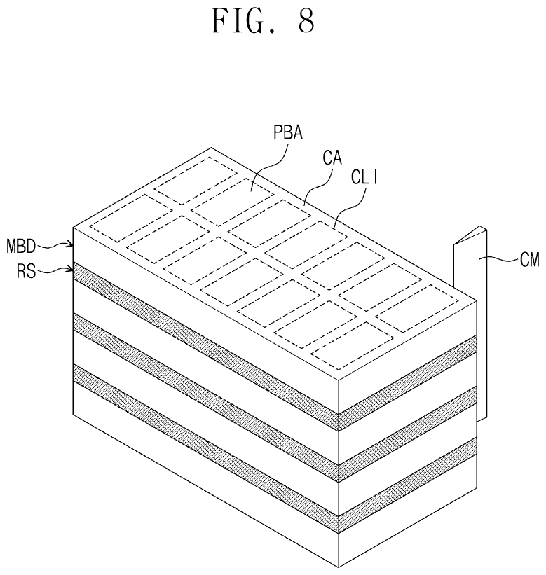

FIGS. 7A and 7B are flowcharts illustrating a method of manufacturing the window illustrated in FIG. 5. FIG. 8 is a perspective view illustrating a cutting process.

A description of, among the components illustrated in FIGS. 7A to 8, the same components as those described with reference to the drawings described above will be omitted or briefly made.

Referring to FIGS. 7A and 8, the preliminary glass PGS (refer to FIG. 1) may be provided through a cutting process (S10). The cutting process (S10) may include an operation of alternately stacking mother boards MBD and resin layers RS in the third direction DR3.

The mother boards MBD may include a material having flexible properties. In an embodiment, the mother boards MBD may include glass. An upper surface of the mother board MBD may include a substrate area PBA and a periphery area CA. A boundary between the substrate area PBA and the periphery area CA may be defined by a cutting line CLI.

Resin layers RS may function to fix stacked mother boards MBD. The resin layers RS may include a material having adhesive properties. In an embodiment, the resin layers RS may include at least one of a resin, an optically clear adhesive, rosin, and wax, for example.

The stacked mother boards MBD and resin layers RS may be cut. The stacked mother boards MBD and resin layers RS may be cut together through a cutting member CM. In an embodiment, the mother boards MBD and the resin layers RS may be separated from each other by a computer numerical control (“CNC”), for example. However, the disclosure is not limited thereto, and the substrate area PBA and the periphery area CA may be separated from each other by a laser. Hereinafter, the substrate area PBA separated from the periphery area CA may be also referred to as the preliminary glass PGS (refer to FIG. 1).

FIGS. 9A and 9B are perspective views illustrating an operation of loading a preliminary glass on the substrate loading unit illustrated in FIG. 1.

A description of, among the components illustrated in FIGS. 9A to 9B, the same components as those described with reference to the drawings described above will be omitted or briefly made.

Referring to FIGS. 7B and 9A, after the cutting process (S10) is completed, an operation (S20) of loading the preliminary glasses PGS on the substrate loading unit CST may be performed. The plurality of preliminary glasses PGS may be fixed between the main frames MF by the (1-1)-th support parts FP1-1 of the substrate loading unit CST. Opposite sides of the preliminary glasses PGS, which is opposite to each other in the second direction DR2, may be disposed between the first fixed portions SPT1 that are adjacent to each other in the first direction DR1. Although not illustrated, the (1-2)-th support parts FP1-2 (refer to FIG. 1) of FIG. 1 may fix the lower area LGS (refer to FIG. 1) of the preliminary glasses PGS.

Referring to FIG. 9B, after the preliminary glasses PGS are fixed by the first fixed portions SPT1, the second support parts FP2 may be disposed on the preliminary glasses PGS. The second support parts FP2 may be coupled to the main frames MF by the fixing screws BT.

The second support parts FP2 may be disposed on the upper areas UGS of the preliminary glasses PGS. The preliminary glasses PGS may be disposed between the second fixed portions SPT2 that are adjacent to each other in the first direction DR1. The second fixed portions SPT2 may fix the preliminary glasses PGS.

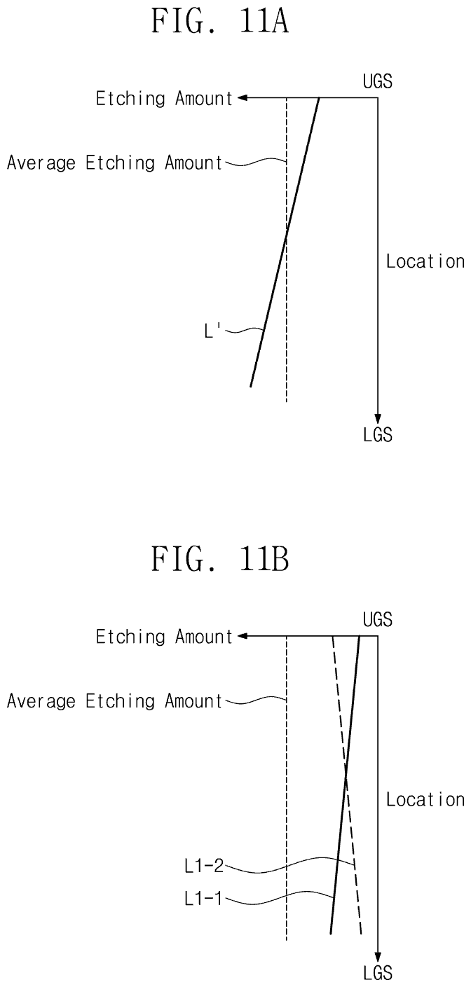

FIGS. 10A to 10F are views illustrating a first etching and cleaning operations. FIG. 11A is a graph depicting an etching amount according to a comparative example. FIG. 11B is a graph depicting an embodiment of an etching amount according to the disclosure.

A description of, among the components illustrated in FIGS. 10A to 10F, the same components as those described with reference to the drawings described above will be omitted or briefly made.

Referring to FIGS. 7B and 10A, after preliminary glass PGS is loaded on the substrate loading unit CST, a first etching and cleaning operation (S30) may be performed. A first etching operation of the first etching and cleaning operation (S30) may include an operation of immersing the substrate loading unit CST in an etching liquid ETL. Hereinafter, the substrate loading unit CST used in the first etching and cleaning operation (S30) may be also referred to as a first substrate loading unit CST.

In detail, a driving unit DU may be disposed on the first substrate loading unit CST. The driving unit DU may be coupled to the first substrate loading unit CST. Then, the upper area UGS of the preliminary glass PGS loaded on the first substrate loading unit CST may be disposed on the lower area LGS. Hereinafter, a state of the preliminary glass PGS, in which the upper area UGS is disposed on the lower area LGS, may be defined as a first state. When the preliminary glass PGS is in the first state, the second support parts FP2 may be disposed on an upper side of the first support parts FP1.

A first accommodation part RF1 and the etching liquid ETL contained in the first accommodation part RF1 may be disposed on a lower side of the driving unit DU and the first substrate loading unit CST. The etching liquid ETL may include hydrogen fluoride (HF), sulfuric acid, nitric acid, or ammonium difluoride.

Referring to FIG. 10B, the driving unit DU may be moved in the third direction DR3. The first substrate loading unit CST connected to the driving unit DU may be moved in the third direction DR3. The first substrate loading unit CST and the preliminary glass PGS may be immersed in etching liquid ETL. The first support parts FP1 may be immersed in etching liquid ETL earlier than immersing the second support parts FP2. The lower area LGS of preliminary glass PGS may be immersed in etching liquid ETL earlier than immersing the upper area UGS. The etching process, in which the lower area LGS is immersed in the etching liquid ETL earlier than immersing the upper area UGS, may be defined as the (1-1)-th etching process (S31).

An interior of the first substrate loading unit CST may be filled with the etching liquid ETL, and the etching liquid ETL may etch a surface of the preliminary glass PGS. In an embodiment, cracks generated on the surface and the edges of preliminary glass PGS in the cutting process (S10) of FIG. 7A may be removed through the etching liquid ETL.

Referring to FIG. 10C, after the (1-1)-th etching process (S31) is performed, the first substrate loading unit CST may be moved upward (or lifted) in the third direction DR3 by the driving unit DU in a lifting process (S32). The first substrate loading unit CST and the preliminary glass PGS may be exposed to an outside from the etching liquid ETL.

Referring to FIG. 10D, the first substrate loading unit CST may be rotated (or turned) about a rotation axis that is parallel to the first direction DR1 by a rotation driving part RDU in a turning process (S33). In an embodiment, the first substrate loading unit CST may be rotated 180 degrees by the rotation driving part RDU. Accordingly, the first substrate loading unit CST may be turned over.

When the first substrate loading unit CST is rotated, the preliminary glass PGS loaded on the first substrate loading unit CST may be rotated. The lower area LGS of the preliminary glass PGS may be disposed on the upper area UGS of the preliminary glass PGS. Hereinafter, the state of the preliminary glass PGS, in which the lower area LGS is disposed on the upper area UGS, may be defined as a second state. When the preliminary glass PGS is in the second state, the second support parts FP2 may be disposed on a lower side than the first support parts FP1.

Referring to FIG. 10E, the first substrate loading unit CST may be moved in the third direction DR3 by the driving unit DU and may be immersed in the etching liquid ETL. The preliminary glass PGS loaded in the first substrate loading unit CST may be immersed in the etching liquid ETL. The second support parts FP2 may be immersed into etching liquid ETL earlier than immersing the first support parts FP1. The upper area UGS of the preliminary glass PGS may be immersed in the etching liquid ETL earlier than immersing the lower area LGS. The preliminary glass PGS may be re-etched by the etching liquid ETL.

Referring to FIGS. 10B and 11A, the graph of FIG. 11A is a graph depicting an etching amount L′ of the preliminary glass PGS when the first substrate loading unit CST is not rotated. The etching amount L′ of preliminary glass PGS may be proportional to a time period, for which it is immersed in the etching liquid ETL. As illustrated in FIG. 10B, the lower area LGS may be immersed in the etching liquid ETL earlier than immersing the upper area UGS, and as illustrated in FIG. 10C, the upper area UGS may be exposed to an outside from the etching liquid ETL earlier than immersing the lower area LGS. Accordingly, the etching amount L′ of the lower area LGS may be greater than the etching amount L′ of the upper area UGS. Accordingly, the etching amount L′ of the preliminary glass PGS may not be uniform, and a quality of the preliminary glass PGS may deteriorate.

Referring to FIGS. 10D, 10E, and 11B, a (1-1)-th etching amount L1-1 illustrated in FIG. 11B is a result that represents an etching amount of the preliminary glass PGS according to the (1-1)-th etching process (S31) (refer to FIG. 7B). A (1-2)-th etching amount L1-2 is a result that represents an etching amount of the preliminary glass PGS according to the (1-2)-th etching process (S34) (refer to FIG. 7B).

After the (1-1)-th etching process (S31) (refer to FIG. 7B) is completed, the preliminary glass PGS may also be turned over upside down as the first substrate loading unit CST is turned over upside down. Unlike the (1-1)-th etching process (S31), the upper area UGS may be immersed in the etching liquid ETL earlier than immersing the lower area LGS. The lower area LGS may be exposed to an outside from the etching liquid ETL earlier than immersing the upper area UGS. Accordingly, as illustrated in FIG. 11B, the etching amount of the upper area UGS and the etching amount of the lower area LGS may be uniform. Accordingly, the quality of the preliminary glass PGS may be improved.

Referring to FIGS. 7B and 10F, after the (1-2)-th etching process (S34) is completed, the first substrate loading unit CST may be lifted from the etching liquid ETL in the third direction DR3 by the driving unit DU in a lifting process (S35).

Although not illustrated, an etching amount of a part corresponding to a folding part FP (refer to FIG. 5) of the preliminary glasses PGS and an etching amount of a part corresponding to the first and second non-folding parts of NFP1 and NFP2 (refer to FIG. 5) of the preliminary glasses PGS may be different. In an embodiment, to facilitate folding of the electronic device ED (refer to FIG. 3), a part of the preliminary glass PGS corresponding to the folding part FP may be etched further than a part of the preliminary glass PGS corresponding to the first and second non-folding parts NFP1 and NFP2.

Although not illustrated, after the (1-2)-th etching process (S34) is completed, an operation (S36) of cleaning and removing the etching liquid ETL that resides on a surface of the preliminary glass PGS may be performed.

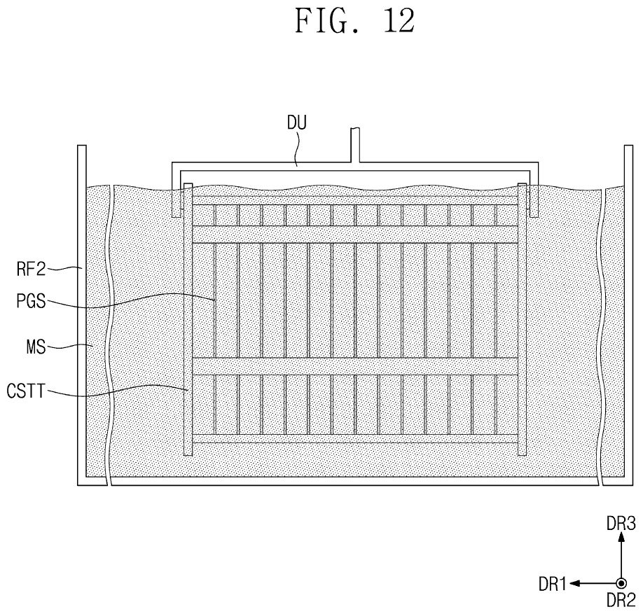

FIG. 12 is a view illustrating a strengthening process of FIG. 7A.

A description of, among the components illustrated in FIG. 12, the same components as those described with reference to the drawings described above will be omitted or briefly made.

Referring to FIG. 12, the preliminary glasses PGS may be loaded on a second substrate loading unit CSTT. The second substrate loading unit CSTT may include or consist of a material that is different from that of the first substrate loading unit CST illustrated in FIG. 10A.

After the preliminary glasses PGS are loaded on the second substrate loading unit CSTT, the preliminary glasses PGS may be immersed in molten salt MS by the driving unit DU. The molten salt MS may be accommodated in the second accommodation part RF2. The second substrate loading unit CSTT and the preliminary glass PGS may be moved toward the molten salt MS in the third direction DR3 by the driving unit DU.

The molten salt MS may strengthen the preliminary glasses PGS. In an embodiment, ions on the surfaces of the preliminary glasses PGS may be replaced with ions contained in the molten salt MS with a relatively large diameter, for example. The surfaces of the preliminary glasses PGS may be strengthened by replacing ions with relatively large diameters.

Referring to FIG. 7A, after the strengthening process (S40) is completed, the preliminary glasses PGS may be loaded on the first substrate loading unit CST (refer to FIG. 9B) from the second substrate loading unit CSTT (refer to FIG. 12). The loading of the preliminary glasses PGS on the first substrate loading unit CST has been described with reference to FIGS. 9A and 9B, and this may be applied to an operation (S50) of loading the preliminary glasses PGS on the first substrate loading unit CST after the strengthening process (S40) is completed.

The strengthened preliminary glasses PGS (refer to FIG. 12) loaded on the first substrate loading unit CST (refer to FIG. 9B) may be re-etched. After the strengthening process (S40) is completed, the second etching and cleaning operation (S60) may be performed.

The first etching and cleaning operation (S30) of the preliminary glasses PGS on the first substrate loading unit CST has been described with reference to FIG. 7B and FIGS. 10A to 10F, and this may also be equally applied to the second etching and cleaning operation (S60) including a (2-1)-th etching process similar to the (1-1)-th etching process (S31) and a (2-2)-th etching process similar to the (1-2)-th etching process (S34), and a description thereof will be omitted.

After the second etching and cleaning operation (S60) is completed, a coating process (S70) may be performed. Through the coating process (S70), a step due to a difference between the etching amounts of the folding part FP (refer to FIG. 5) and the first and second non-folding parts NFP1 and NFP2 (refer to FIG. 5) may be eliminated. When the coating process (S70) is completed, the window WIN of FIG. 5 may be manufactured.

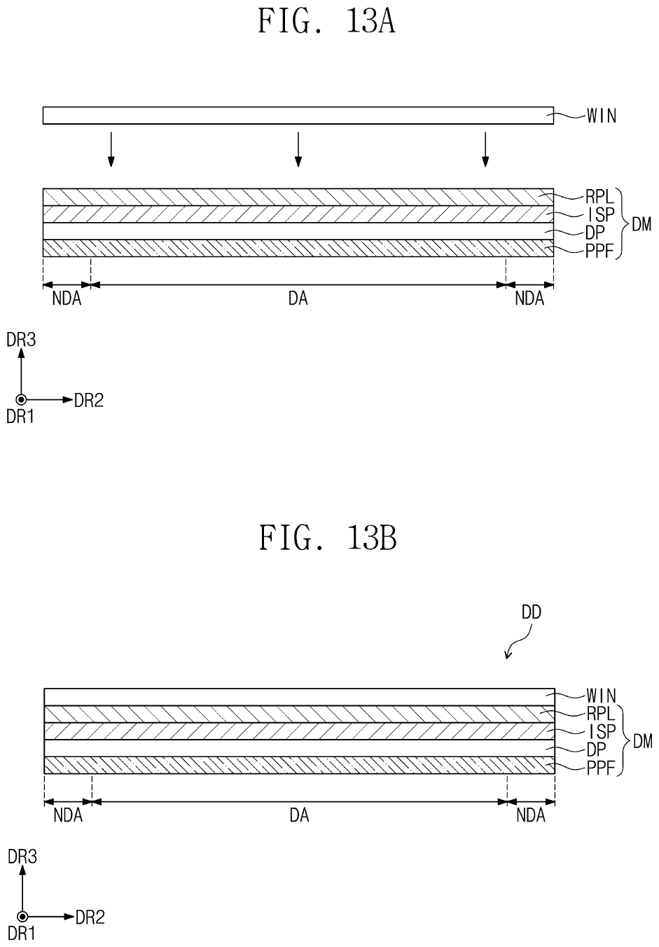

FIGS. 13A and 13B are views illustrating a process of assembling a display module and a window.

A description of, among the components illustrated in FIGS. 13A to 13B, the same components as those described with reference to the drawings described above will be omitted or briefly made.

Referring to FIGS. 7A, 13A, and 13B, after the coating operation (S70) is completed, an inspection and assembly operation (S80) may be performed. As a result of the inspection, when the window WIN meets preset quality standards, it may be combined with the display module DM. As the window WIN is combined with the display module DM, the display device DD may be manufactured.

In an embodiment of the disclosure, after the (1-1)-th etching operation is performed on the window loaded on the substrate loading unit, the substrate loading unit may be rotated and be turned over upside down. The (1-2)-th etching operation may be performed on the window loaded on the substrate loading unit turned over upside down. Accordingly, an upper side of the window and a lower side of the window may be uniformly etched.

Although the disclosure has been described with reference to the embodiments, it will be appreciated by an ordinary skilled in the art, to which the disclosure pertains, that the disclosure may be modified and changed within the scope of the appended claims without departing from the spirits and technical field of the disclosure. Therefore, the technical scope of the disclosure should not be limited to the detailed description of the specification, but all the technical ideas in the claims and the equivalents to the claims fall within the scope of the disclosure.

What is claimed is:

1. A method of manufacturing a display device, the method comprising:
providing a preliminary glass;
loading the preliminary glass on a first substrate loading unit;
performing a (1-1)-th etching process of etching a surface of the preliminary glass by immersing the first substrate loading unit in an etching liquid;
rotating the first substrate loading unit about a rotation axis being parallel to a first direction and turning the first substrate loading unit over;
performing a (1-2)-th etching process of re-etching the surface of the preliminary glass by immersing the first substrate loading unit in the etching liquid; and
strengthening the preliminary glass.

2. The method of claim 1, wherein the first substrate loading unit includes:
a plurality of main frames being spaced apart from each other in the first direction;
a plurality of first support parts disposed between the plurality of main frames, and disposed on a lower side of the preliminary glass and opposite sides of the preliminary glass being opposite to each other in a second direction crossing the first direction; and
a second support part disposed on an upper side of the preliminary glass.

3. The method of claim 2, wherein the loading the preliminary glass includes:
inserting the preliminary glass between the plurality of first support parts; and
disposing the second support part on the upper side of the preliminary glass and fixing the second support part to the plurality of main frames.

4. The method of claim 3, wherein the first substrate loading unit further includes:
a fixing screw disposed on an outer side of the plurality of main frames,
wherein the plurality of main frames and the second support part are coupled to each other by the fixing screw.

5. The method of claim 2, wherein a portion of the preliminary glass, which is closer to the plurality of first support parts than to the second support part, is defined as a lower area,
wherein a portion of the preliminary glass, which is closer to the second support part than to the first support part, is defined as an upper area, and
wherein in the performing the (1-1)-th etching process, the lower area is immersed in the etching liquid earlier than immersing the upper area.

6. The method of claim 5, wherein in the performing the (1-2)-th etching process, the upper area is immersed in the etching liquid earlier than immersing the lower area.

7. The method of claim 2, wherein the first substrate loading unit further includes a rotation driving part coupled to the plurality of main frames, and
the plurality of main frames, the plurality of first support parts, and the second support part are rotated about the rotation axis being parallel to the first direction by the rotation driving part.

8. The method of claim 2, wherein each of the plurality of first support parts includes:
a first bar portion fixed to the plurality of main frames; and
a first fixed portion disposed on a side surface of the first bar portion, which faces the preliminary glass, and
wherein the second support part includes:
a second bar portion fixed to the plurality of main frames; and
a second fixed portion disposed on a side surface of the second bar portion, which faces the preliminary glass.

9. The method of claim 1, wherein the providing the preliminary glass includes:
stacking a plurality of mother boards from a lower side to an upper side; and
separating the preliminary glass through a cutting machine disposed on an upper side of the plurality of mother boards.

10. The method of claim 2, wherein the strengthening the preliminary glass includes:
loading the preliminary glass loaded on the first substrate loading unit, on a second substrate loading unit;
moving the second substrate loading unit toward molten salt, and immersing the preliminary glass in the molten salt; and
moving the second substrate loading unit and lifting the second substrate loading unit from the molten salt.

11. The method of claim 10, further comprising:
loading a strengthened preliminary glass on the first substrate loading unit;
performing a (2-1)-th etching process of etching the surface of the preliminary glass by immersing the preliminary glass in the etching liquid;
rotating the first substrate loading unit about the rotation axis being parallel to the first direction and turning the first substrate loading unit over; and
performing a (2-2)-th etching process of re-etching the surface of the preliminary glass by immersing the first substrate loading unit in the etching liquid.

12. The method of claim 11, wherein a portion of the preliminary glass, which is closer to the plurality of first support parts than to the second support part, is defined as a lower area,
wherein a portion of the preliminary glass, which is closer to the second support part than to the first support part, is defined as an upper area, and
wherein in the performing the (2-1)-th etching process, the lower area is immersed in the etching liquid earlier than immersing the upper area, and
in the performing the (2-2)-th etching process, the upper area is immersed in the etching liquid earlier than immersing the lower area.

13. A substrate loading unit comprising:
a plurality of main frames each having a plane defined by a first direction and a second direction crossing the first direction, and being spaced apart from each other in the first direction;
a plurality of first support parts disposed between inner surfaces of the plurality of main frames facing each other in the first direction, disposed on a lower side of a preliminary glass disposed between the plurality of main frames, and disposed on opposite sides of the preliminary glass, which are opposite to each other in the second direction; and
a rotation driving part disposed on an outer side of any one of the plurality of main frames.

14. The substrate loading unit of claim 13, further comprising:
a second support part disposed on an upper side of the preliminary glass, and extending in the first direction.

15. The substrate loading unit of claim 14, wherein the second support part includes:
a second bar portion fixed to the plurality of main frames; and
a second fixed portion disposed on a side surface of the second bar portion, which faces the preliminary glass.

16. The substrate loading unit of claim 14, wherein a state, in which the plurality of first support parts is disposed on a lower side of the second support part, is defined as a first state, a state, in which the plurality of first support parts is disposed on an upper side of the second support part, is defined as a second state, and the first state and the second state are converted by the rotation driving part.

17. The substrate loading unit of claim 14, further comprising:
fixing screws passing through openings defined in the plurality of main frames, and
wherein the second support part and the plurality of main frames are coupled to each other by the fixing screws.

18. The substrate loading unit of claim 14, wherein the plurality of first support parts includes:
(1-1)-th support parts disposed on opposite sides of the preliminary glass being opposite to each other in the second direction; and
a (1-2)-th support part disposed on a lower side of the preliminary glass, and facing the second support part.

19. The substrate loading unit of claim 18, wherein the (1-1)-th support parts include:
first bar portions extending in the first direction, and coupled to the plurality of main frames; and
first fixed portions disposed on side surfaces of the first bar portions, which face the preliminary glass.

20. The substrate loading unit of claim 19, wherein the first fixed portions are arranged in the first direction along the first bar portions, and the preliminary glass is disposed between the first fixed portions next to each other in the first direction.

21. An electronic device comprising;
a display device including a display module and a window disposed on the display module, and
a case accommodating the display device,
the window produced by a process comprising,
providing a preliminary glass;
loading the preliminary glass on a substrate loading unit;
performing a (1-1)-th etching process of etching a surface of the preliminary glass by immersing the substrate loading unit in an etching liquid;
rotating the substrate loading unit about a rotation axis being parallel to a first direction and turning the substrate loading unit over;
performing a (1-2)-th etching process of re-etching the surface of the preliminary glass by immersing the substrate loading unit in the etching liquid; and
strengthening the preliminary glass, and
wherein the strengthened the preliminary glass is defined the window.
